(19) United States
(12) Patent Application Publication
(10) Pub. No.: US 2024/0355828 A1
(43) Pub. Date: Oct. 24, 2024

(54) DISPLAY DEVICE

(71) Applicant: Samsung Display Co., Ltd., Yongin-Si (KR)

(72) Inventors: Keun Woo KIM, Yongin-si (KR); Doo Na KIM, Yongin-si (KR); Sang Sub KIM, Yongin-si (KR); Bum Mo SUNG, Yongin-si (KR)

(21) Appl. No.: 18/601,840

(22) Filed: Mar. 11, 2024

(30) Foreign Application Priority Data
Apr. 24, 2023 (KR) 10-2023-0053474

(51) Int. Cl. H01L 27/12; H10K 59/121; H10K 59/131

(52) U.S. Cl. CPC H01L 27/1225; H10K 59/1213; H10K 59/131

(57) ABSTRACT

The disclosure relates to a display device, and more particularly, to a display device capable of reducing a dead space area while improving current driving capability of pull-up and pull-down transistors. According to an embodiment of the disclosure, a substrate having a display area and a non-display area; pixels arranged in the display area of the substrate; and a gate driving circuit disposed in the non-display area of the substrate and connected to a transistor of the pixel. The gate driving circuit includes a pull-up transistor and a pull-down transistor. At least one of the pull-up and pull-down transistors includes a plurality of sub-transistors including a plurality of gate electrodes, and wherein the sub-transistors shares at least one of the gate electrodes.

### CROSS-REFERENCE TO RELATED APPLICATION

This application claims priority from Korean Patent Application No. 10-2023-0053474 filed on Apr. 24, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device capable of reducing a dead space area while improving current driving capability of a pull-up transistor and a pull-down transistor.

### 2. Description of the Related Art

A thin film transistor (TFT) has been used in various fields. In particular, it has been used as a switching and driving element in flat display devices such as liquid crystal displays (LCD), organic light-emitting diode (OLED) displays, and electrophoretic displays.

### SUMMARY

Aspects of the present disclosure may provide a display device in which a current driving ability of a pull-up transistor and a pull-down transistor is improved and a size of a dead space is reduced.

The objects of the present disclosure are not limited to those mentioned above and additional objects of the present disclosure, which are not mentioned herein, will be clearly understood by those skilled in the art from the following description of the present disclosure.

According to an embodiment of the disclosure, a display device comprising: substrate having a display area and a non-display area; pixels arranged in the display area of the substrate; and a gate driving circuit disposed in the non-display area of the substrate and connected to a transistor of the pixel; wherein the gate driving circuit includes a pull-up transistor and a pull-down transistor, wherein at least one of the pull-up transistor and the pull-down transistor includes a plurality of sub-transistors including a plurality of gate electrodes, and wherein the plurality of sub-transistors shares at least one of the plurality of gate electrodes.

In an embodiment, the plurality of gate electrodes comprises: a first gate electrode disposed on the substrate; a second gate electrode disposed on the first gate electrode; and a third gate electrode disposed on the second gate electrode.

In an embodiment, the plurality of sub-transistors shares the second gate electrode.

In an embodiment, the plurality of sub-transistors comprises a first sub-transistor and a second sub-transistor connected in parallel.

In an embodiment, the first sub-transistor comprises: the first gate electrode; the second gate electrode; and a first active layer disposed between the first gate electrode and the second gate electrode.

In an embodiment, the second sub-transistor comprises: the second gate electrode; the third gate electrode; and a second active layer disposed between the second gate electrode and the third gate electrode.

In an embodiment, a portion corresponding to a first drain electrode of the first sub-transistor among the first active layer and a portion corresponding to a second drain electrode of the second sub-transistor among the second active layer are connected to each other.

In an embodiment, wherein the first drain electrode and the second drain electrode are connected to each other through a contact hole of an insulating layer.

In an embodiment, a portion corresponding to a first source electrode of the first sub-transistor among the first active layer and a portion corresponding to a second source electrode of the second sub-transistor among the second active layer are connected to each other.

In an embodiment, the first source electrode and the second source electrode are connected to each other through a contact hole of an insulating layer.

In an embodiment, the first gate electrode, the second gate electrode and the third gate electrode are connected to each other through a contact hole of an insulating layer.

In an embodiment, the first active layer and the second active layer contain the same semiconductor material.

In an embodiment, the first active layer and the second active layer each contains oxide semiconductor material.

In an embodiment, the oxide semiconductor material includes an oxide semiconductor including indium-gallium-zinc-oxide (IGZO) or indium-gallium-zinc-tin oxide (IGZTO).

In an embodiment, the first gate electrode, the second gate electrode and the third gate electrode overlap each other.

In an embodiment, the first active layer and the second active layer overlap each other.

According to the display device of the present disclosure, since the pull-up transistor and the pull-down transistor include a plurality of sub-transistors connected in parallel, current driving ability of the pull-up transistor and the pull-down transistor can be improved. In addition, since the plurality of sub-transistors share at least one gate electrode, the size of the pull-up transistor and the pull-down transistor can be reduced. Accordingly, the size of a gate driving circuit including the pull-up transistor and the pull-down transistor may be reduced, and accordingly, the area of a non-display area (e.g., dead space) in which the gate driving circuit is disposed may be reduced.

It should be noted that the effects of the present disclosure are not limited to those described above, and other effects not mentioned will be clearly understood by those skilled in the art from the description below.

### BRIEF DESCRIPTION OF THE DRAWINGS

The above and other aspects and features of the present disclosure will become more apparent by describing in detail exemplary embodiments thereof with reference to the attached drawings.

FIG. 1 is a perspective view of a display device according to one embodiment.

FIG. 2 is a plan view of a display device according to one embodiment.

FIG. 3 is a block diagram of a display device according to one embodiment.

FIG. 4 is a circuit diagram of a pixel of a display device according to one embodiment.

FIG. 5 is a block diagram of the first sub-gate driver of FIG. 3.

FIG. 6 is a circuit diagram of an embodiment of the n^{th} stage of FIG. 5.

FIG. 7 is a plan view illustrating the layout of the ninth transistor of FIG. 6.

FIG. 8 is a cross-sectional view taken along line I-I′ of FIG. 7.

FIG. 9 is a cross-sectional view taken along line II-II′ of FIG. 7.

FIG. 10 is a circuit diagram of one stage included in the emission control driver of FIG. 3.

### DETAILED DESCRIPTION OF THE EMBODIMENTS

Advantages and features of the present disclosure and methods of achieving the same will become apparent with reference to the exemplary embodiments described below in detail in conjunction with the accompanying drawings. However, the present disclosure is not limited to the exemplary embodiments described below, but may be implemented in various different forms, the exemplary embodiments are described in order to make the present disclosure complete and allow one of ordinary skill in the art to which the present disclosure pertains to completely recognize the scope of the present disclosure and the scope of the subject matter defined in the claims.

In this disclosure, an element or layer referred to as being “on” another element or layer includes both a case in which the element or layer is directly on another element or layer and a case in which the element or layer is on another element or layer with one or more other elements or layers interposed therebetween. The same reference numbers indicate the same components throughout the specification. Shapes, sizes, proportions, angles, numbers, and the like, shown in the drawings are examples and may be simplified or exaggerated to improve understanding, and embodiments of the present disclosure are not limited to those illustrated in the drawings.

It will be understood that, although the terms “first”, “second”, and the like may be used to describe various components, these components should not be limited by these terms. These terms are only used to distinguish one component from another component. Accordingly, a first component discussed below could be termed a second component without departing from the teachings of the present disclosure.

Each feature of the various exemplary embodiments of the present disclosure may be partially or entirely coupled or combined with each other and may be technically capable of various interlocking and driving, and each exemplary embodiment may be implemented independently of each other or may be implemented together in an association relationship.

Hereinafter, embodiments will be described in detail with reference to the accompanying drawings.

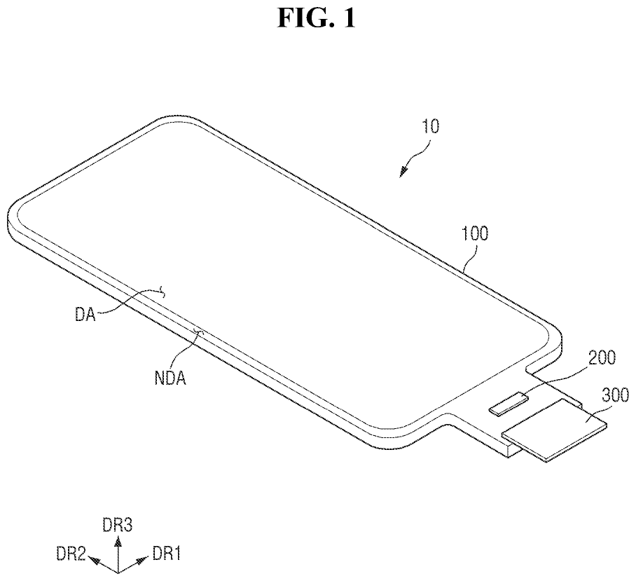

FIG. 1 is a perspective view of a top of a display device 10 according to one embodiment. The terms “upper,” “top” and “top surface” as used herein refer to an upward direction (i.e., a third direction DR3 in FIG. 1) or a main viewing side with respect to a display panel. The terms “lower,” “bottom” and “bottom surface” as used herein refer to a downward direction (i.e., a direction opposite to the third direction DR3) with respect to the display panel. Further, “left”, “right”, “upper” and “lower” refer to directions when the display device 10 is viewed from above. For example, “left” refers to an opposite direction of a first direction DR1, “right” refers to the first direction DR1, “upper” refers to a second direction DR2, and “lower” refers to an opposite direction of the second direction DR2.

The display device 10 displays an image on a screen through a display area DA and may be employed as all or part of various devices. Examples of applications of the display device 10 may include, but are not limited to, a smartphone, a mobile phone, a tablet PC, a personal digital assistant (PDA), a portable multimedia player (PMP), a television, a game machine, a wristwatch-type electronic device, a head-mounted display, a monitor of a personal computer, a laptop computer, a car navigation system, a car's dashboard display, a digital camera, a camcorder, an external billboard, an electronic billboard, various medical devices, various inspection devices, various household appliances such as a refrigerator and a washing machine, an Internet-of-Things device, and the like.

In addition, the display device 10 may be a light-emitting display device such as an organic light-emitting display device using organic light-emitting diodes, a quantum dot display device including a quantum dot light-emitting layer, an inorganic light-emitting display device including an inorganic semiconductor, and a micro light-emitting display device using micro light-emitting diodes. Hereinafter, an organic light-emitting display device will be described as an example of the display device 10, and the organic light-emitting display device applied to the embodiment will be simply referred to as the display device 10 unless special distinction is required. However, the embodiment is not limited to an organic light-emitting display device, and other display devices mentioned above or known in the art may be applied within the same scope of technical spirit.

The display device 10 may include a display panel 100, a display driving circuit 200, and a circuit board 300.

The display panel 100 may, in plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a curvature or may be right-angled. The planar shape of the display panel 100 is not limited to the rectangular shape, and the display panel 100 may be formed, for example, in another polygonal shape, a circular shape or an elliptical shape. The display panel 100 may be formed to be flat, but embodiments are not limited thereto. For example, the display panel 100 may include a curved portion at left and right edges and having a constant curvature or a varying curvature. Alternatively, the display panel 100 may be flexible so that the display panel 1000 can be curved, bent, folded, or rolled.

The display panel 100 may be divided into a display area DA displaying an image or video and a non-display area NDA disposed around the display area DA, in a plan view, according to whether display is performed.

The display area DA may include a plurality of pixels. The pixel is a basic unit for displaying a screen. The pixels may include, but are not limited to, a red pixel, a green pixel, and a blue pixel. The pixels may further include a white pixel. The plurality of pixels may be alternately arranged in plan view. For example, the pixels may be arranged in a matrix or array, but the present disclosure is not limited thereto.

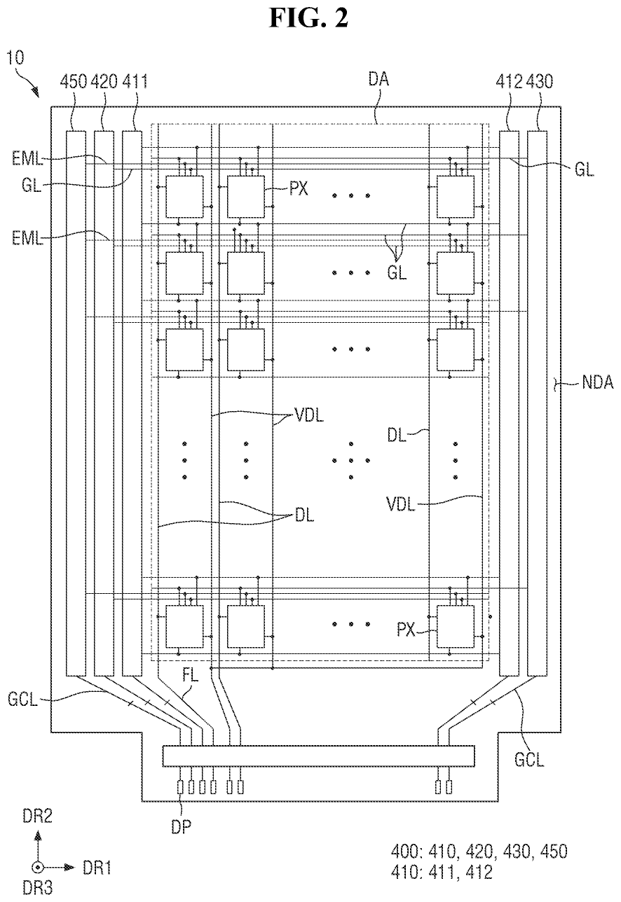

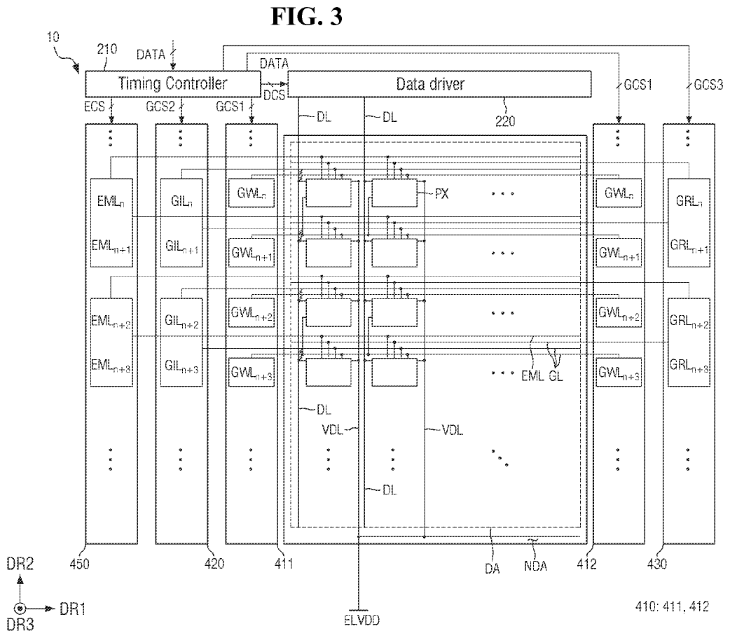

The non-display area NDA may be disposed around the display area DA. A black matrix may be disposed in the non-display area NDA to prevent light emitted from adjacent pixels from leaking out through the non-display area NDA. In addition, the non-display area NDA may include circuitry such as a driver circuit for controlling or driving a plurality of pixels and a plurality of lines for applying an electric signal to each of the plurality of pixels. Components in the non-display area NDA are described further below with reference to FIGS. 2 and 3.

The non-display area NDA may surround the display area DA as illustrated in FIG. 1. That is, the display area DA may be formed in a generally quadrilateral shape, and the non-display area NDA may be disposed around four sides of the display area DA. However, the present disclosure is not limited thereto, and the display area DA may be partially surrounded by the non-display area NDA. For example, the non-display area NDA may be disposed only around three sides of the display area DA. In this case, the other side of the display area DA may form an edge of the display device 10.

The display driving circuit 200 may be formed as an integrated circuit (IC) and attached onto the display panel 100 by a chip on glass (COG) method, a chip on plastic (COP) method, or an ultrasonic bonding method, but the present disclosure is not limited thereto. For example, the display driving circuit 200 may be attached on the circuit board 300.

The circuit board 300 may be attached onto the pads DP using an anisotropic conductive film. Accordingly, lead lines of the circuit board 300 may be electrically connected to the pads DP. The circuit board 300 may be a flexible printed circuit board, a printed circuit board, or a flexible film such as a chip on film.

FIG. 2 is a plan view of a display device according to one embodiment. FIG. 3 is a block diagram of a display device according to one embodiment.

Referring to FIGS. 2 and 3, pixels PX, gate lines GL, emission lines EML, data lines DL, and a driving voltage line VDL connected to the sub-pixels PX may be disposed on the display panel 100. The gate lines GL and the emission lines EML may extend in the first direction DR1, and the data lines DL and the driving voltage line VDL may extend in the second direction DR2 crossing the first direction DR1. The driving voltage line VDL may extend in the second direction DR2 in the display area DA. The driving voltage line VDL may include multiple lines that extend in the second direction and are connected to each other in the non-display area NDA.

Each of the pixels PX may be connected to at least one of the gate lines GL, one of the data lines DL, at least one of the emission lines EML, and the driving voltage line VDL. FIG. 2 illustrates an example in which each of the pixels PX is connected to three gate lines GL, one data line DL, one emission line EML, and the driving voltage line VDL, but the embodiments are not limited thereto. For example, each of the pixels PX may be connected to two or fewer gate lines GL instead of three gate lines GL, or may be connected to four or more gate lines GL.

Each of the pixels PX may include a driving transistor, at least one switching transistor, a light-emitting element, and a capacitor. The driving transistor and the at least one switching transistor may be thin film transistors. The at least one switching transistor may be turned on or off according to a gate signal applied from the gate line to act as a switching element. For example, when a transistor disposed between the data line and the gate electrode of the driving transistor is turned on by a gate signal, the data voltage of the data line may be applied to the gate electrode of the driving transistor. The light-emitting element in each pixel PX may be an organic light-emitting diode including a first electrode, an organic light-emitting layer and a second electrode. The light-emitting element may emit light according to the driving current of the driving transistor. The capacitor may serve to keep constant the data voltage applied to the gate electrode of the driving transistor.

The display driving circuit 200 may include a timing controller 210, a data driver 220, and a plurality of voltage lines as illustrated in FIG. 3.

The timing controller 210 may receive digital video data DDATA and timing signals from the circuit board 300. The timing controller 210 may generate a plurality of gate control signals GCS1, GCS2, and GCS3 for controlling an operation timing of each of a plurality of gate drivers 410, 420, and 430 according to the timing signals, may generate an emission control signal ECS for controlling an operation timing of an emission control driver 450, and may generate a data control signal DCS for controlling an operation timing of the data driver 220. For example, the timing controller 210 may generate the first gate control signal GCS1, the second gate control signal GCS2, and the third gate control signal GCS3 according to the timing signals. Further, the timing controller 210 may output the first gate control signal GCS1 to the first gate driver 410, output the second gate control signal GCS2 to the second gate driver 420, and output the third gate control signal GCS3 to the third gate driver 430.

The timing controller 210 may output, through the gate control lines GCL, the gate control signals GCS1, GCS2, and GCS3 to the gate drivers 410, 420, and 430, respectively, and the emission control signal ECS to the emission control driver 450. The timing controller 210 may output the digital video data DDATA and the data control signal DCS to the data driver 220.

The data driver 220 may convert the digital video data DDATA into analog data voltages to output the analog data voltages to the data lines DL through fan-out lines FL.

Each of the plurality of voltage lines may be supplied with a voltage from a power supply unit. The plurality of voltage lines may include the driving voltage line VDL for applying a driving voltage ELVDD and a common voltage line for applying a common voltage. The driving voltage may be a high potential voltage for driving organic light-emitting diodes or other light emitting elements in the pixels PX, and the common voltage line may be a low potential voltage for driving the organic light-emitting diodes or other light emitting elements in the pixels PX. For example, the driving voltage may have a higher potential than the common voltage.

The non-display area NDA may contain a gate driving circuit 400 for applying gate signals to the gate lines GL, the fan-out lines FL between the data lines DL and the display driving circuit 200, and the pads DP connected to the display driving circuit 200. The display driving circuit 200 and the pads DP may be disposed adjacent to an edge of the lower side of the display panel 100.

The gate driving circuit 400 may be electrically connected to the display driving circuit 200 through the gate control lines GCL. The gate driving circuit 400 may receive the gate control signals GCS1, GCS2, and GCS3 and the emission control signal ECS from the display driving circuit 200 through the gate control lines GCL.

The gate driving circuit 400 may generate gate signals according to the gate control signals GCS, and sequentially output the gate signals to the gate lines GL. Further, the gate driving circuit 400 may generate emission signals according to the emission control signal ECS and may sequentially output the emission signals to the emission lines EML.

The gate driving circuit 400 may include a plurality of thin film transistors. The gate driving circuit 400 may be formed on or using the same layer or layers in which the thin film transistors of the pixels PX are formed. The gate driving circuit 400 may be disposed in the non-display area NDA on both sides (i.e., left and right sides) of the display area DA. Such a structure may advantageously reduce the length of the non-display area NDA in the first direction DR1 on each of the left and right sides of the display area DA. However, the embodiments are not limited thereto. For example, the gate driving circuit 400 may be disposed on either the left side or the right side of the display area DA.

The gate driving circuit 400 may include the first gate driver 410, the second gate driver 420, the third gate driver 430, and the emission control driver 450.

FIGS. 2 and 3 illustrate an example in which the first gate driver 410 includes a first sub-gate driver 411 disposed on one side of the non-display area NDA, for example, on the left side of the non-display area and a second sub-gate driver 412 disposed on the other side of the non-display area NDA, for example, on the right side of the non-display area NDA, and each of the first sub-gate driver 411 and the second sub-gate driver 412 applies a gate signal. The present disclosure is not limited thereto. Alternatively, the gate driving circuit 400 may include one first gate driver 410, which may be disposed on either one side or the other side of the non-display area NDA.

The second gate driver 420 and the third gate driver 430 may be disposed on different sides of the non-display area NDA. For example, as illustrated in FIG. 3, when the second gate driver 420 is disposed on one side of the non-display area NDA, the third gate driver 430 may be disposed on the other side of the non-display area NDA, and conversely, when the second gate driver 420 is disposed on the other side of the non-display area NDA, the third gate driver 430 may be disposed on one side of the non-display area NDA.

At least two voltage lines among voltage lines for applying voltages to the gate lines GL may be connected to each of the gate drivers 410, 420, and 430. The voltage line or lines for applying a voltage to the emission lines EML may be connected to the emission control driver 450.

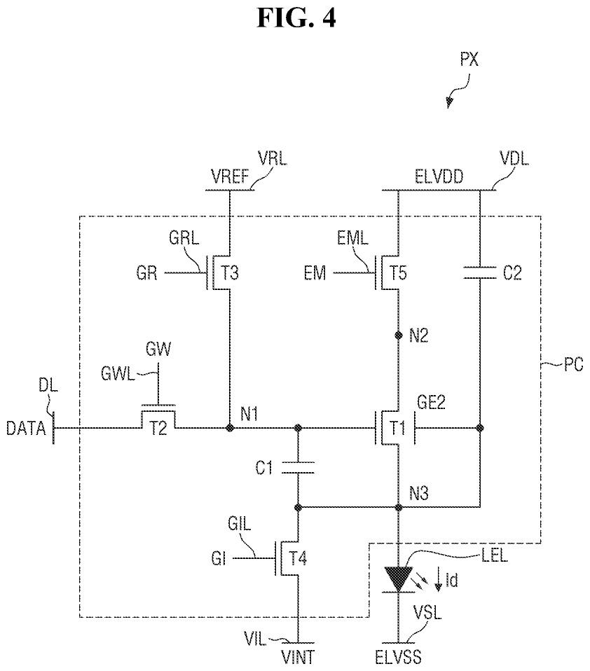

FIG. 4 is a circuit diagram of a pixel of a display device according to one embodiment.

Referring to FIG. 4, the pixel PX may include a light-emitting element LEL (e.g., an organic light-emitting diode) as a display element and a pixel circuit PC connected to the light-emitting element LEL. The pixel circuit PC may include first to fifth transistors T1 to T5 and first and second capacitors C1 and C2. The first transistor T1 may be a driving transistor in which a size of a source-drain current is determined according to a gate-source voltage, and each of the second to fifth transistors T2 to T5 may be a switching transistor that is turned on/off according to the gate-source voltage, substantially a gate voltage. The first to fifth transistors T1 to T5 may be implemented as thin film transistors. According to the type (p-type or n-type) and/or the operating condition of the transistor, the first electrode of each of the first to fifth transistors T1 to T5 may be a source electrode or a drain electrode, and the second electrode may be an electrode different from the first electrode. For example, when the first electrode is the source electrode, the second electrode may be the drain electrode.

The pixel PX may be connected to a first gate line GWL that transmits a first gate signal GW, a second gate line GIL that transmits a second gate signal GI, a third gate line GRL that transmits a third gate signal GR, an emission line EML that transmits an emission signal EM, and a data line DL that transmits a data signal DATA.

The first gate driver 410 (e.g., the first sub-gate driver 411 and the second sub-gate driver 412) may apply the first gate signal GW to the first gate lines GWL. The second gate driver 420 may apply the second gate signal GI to the second gate lines GIL. The first gate driver 430 may apply the third gate signal GR to the third gate lines GRL. The emission control driver 450 may apply the emission signal EM to the emission lines EML.

The driving voltage line VDL may transmit the driving voltage ELVDD to the first transistor T1. An initialization voltage line VIL may transmit an initialization voltage VINT to the light-emitting element LEL (e.g., an organic light-emitting diode). A reference voltage line VRL may transmit a reference voltage VREF to the gate electrode of the first transistor T1. Meanwhile, depending on the pixel structure, the initialization voltage line VIL described above may include a plurality of initialization voltage lines VIL (e.g., a first initialization voltage line and a second initialization voltage line that transmit initialization voltages of different sizes.

A plurality of first to fifth transistors T1 to T5 may include an oxide semiconductor material. Since the oxide semiconductor has high carrier mobility and low leakage current, the voltage drop is not large although the driving time is long. That is, in the case of an oxide semiconductor, since a color change of an image due to a voltage drop is not large even during low-frequency driving, low-frequency driving is possible. Accordingly, a display device preventing the generation of leakage current and having reduced power consumption may be implemented by the plurality of first to fifth transistors T1 to T5 including an oxide semiconductor material. In addition, in the case of using an oxide semiconductor transistor, a crystallization process by excimer laser annealing (ELA) is not required to form a low-temperature polycrystalline silicon (LTPS) semiconductor transistor, and thus the manufacturing cost of the display panel 100 may be reduced, so that it is advantageous for implementation of a large-area display device.

The oxide semiconductor is sensitive to light, so that a fluctuation in current amount and the like may occur due to light from the outside. Accordingly, positioning a metal layer under the oxide semiconductor may be considered to absorb or reflect light from the outside. The metal layer positioned below the oxide semiconductor of each of the first to fifth transistors T1 to T5 may function as a lower gate electrode (e.g., a counter gate electrode). That is, the first to fifth transistors T1 to T5 may be double gate transistors having two gate electrodes (e.g., a first gate electrode and a second gate electrode, or a gate electrode and a counter gate electrode).

The first transistor T1 has the first gate electrode connected to a first node N1 (or gate node), the second gate electrode connected to a third node N3, a first electrode connected to a second node N2, and a second electrode connected to the third node N3. The second gate electrode GE2 of the first transistor T1 may be connected to the second electrode of the first transistor T1 to be controlled by a voltage applied to the second electrode of the first transistor T1, which may improve the output saturation characteristics of the first transistor T1. The first electrode of the first transistor T1 may be connected to the driving voltage line VDL via the fifth transistor, and the second electrode of the first transistor T1 may be connected to the pixel electrode (e.g., an anode electrode) of the light-emitting element LEL. The first transistor T1 may serve as a driving transistor and may control the magnitude (e.g., current amount) of a driving current Id flowing to the light-emitting element LEL by receiving the data signal DATA according to the switching operation of the second transistor T2.

The second transistor T2 (e.g., data writing transistor) includes a gate electrode connected to the first gate line GWL, a first electrode connected to the data line DL, and a second electrode connected to the first node N1 (or the gate electrode of the first transistor T1). The second transistor T2 may be turned on according to the first gate signal GW transmitted to the first gate line GWL to electrically connect the data line DL to the first node N1 and may transmit the data signal DATA from the data line DL to the first node N1.

The third transistor T3 (e.g., a first initialization transistor) includes a gate electrode connected to the third gate line GRL, a first electrode connected to the reference voltage line VRL, and a second electrode connected to the first node N1 (or the gate electrode of the first transistor T1). The third transistor T3 may be turned on or off according to the third gate signal GR transmitted to the third gate line GRL and, when turned on, transmits the reference voltage VREF from the reference voltage line VRL to the first node N1.

The fourth transistor T4 (e.g., the second initialization transistor) includes a gate electrode connected to the second gate line GIL, a first electrode connected to the third node N3 (or the second electrode of the first transistor T1), and a second electrode connected to the initialization voltage line VIL. The fourth transistor T4 may be turned on or off according to the second gate signal GI transmitted to the second gate line GIL and, when turned on, transmits the initialization voltage VINT from the initialization voltage line VIL to the third node N3.

The fifth transistor T5 (e.g., a light-emitting transistor) includes a gate electrode connected to the emission line EML, a first electrode connected to the driving voltage line VDL, and a second electrode connected to the second node (or the first electrode of the first transistor T1). The fifth transistor T5 may be turned on or off according to the emission signal EM transmitted to the emission line EML.

The first capacitor C1 may be connected between the first node N1 and the third node N3. The first electrode of the first capacitor C1 may be connected to the gate electrode of the first transistor T1, and the second terminal thereof may be connected to the second gate electrode GE2 and the second electrode of the first transistor T1, the first electrode of the fourth transistor T4, and the pixel electrode (e.g., anode electrode) of the light-emitting element LEL. The first capacitor C1 may be a storage capacitor and may store a voltage corresponding to a threshold voltage and a data signal of the first transistor T1.

The second capacitor C2 may be connected between the third node N3 and the driving voltage line VDL. The first electrode of the second capacitor C2 may be connected to the driving voltage line VDL, and the second electrode thereof may be connected to the second gate electrode GE2 and the second electrode of the first transistor T1, the second electrode of the first capacitor C1, the first electrode of the fourth transistor T4, and the pixel electrode of the light-emitting element LEL. The capacitance of the first capacitor C1 may be greater than the capacitance of the second capacitor C2.

The light-emitting element LEL may include a pixel electrode (e.g., an anode electrode) and a counter electrode (e.g., a cathode electrode) facing the pixel electrode, and a common voltage ELVSS may be applied to the counter electrode. The counter electrode may be connected to a common voltage line VSL transmitting a common voltage. The counter electrode may be a common electrode commonly shared by the plurality of pixels PX.

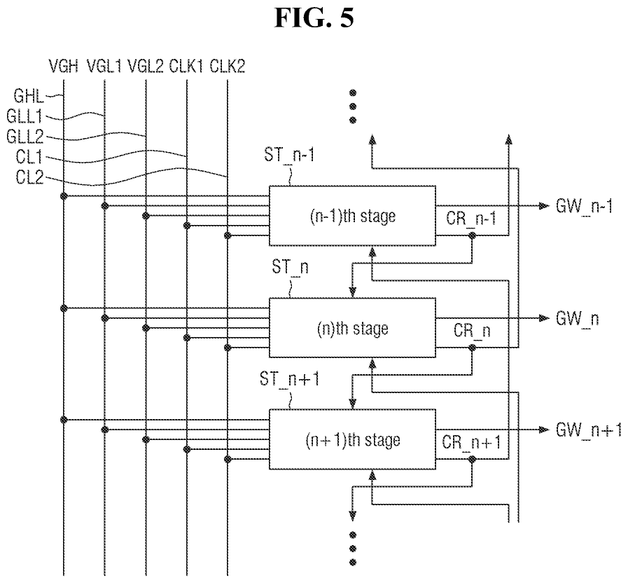

FIG. 5 is a block diagram of the first sub-gate driver 411 of FIG. 3.

As shown in FIG. 5, the first sub-gate driver 411 may include a plurality of stages.

Each of stages ST_n−1, ST_n, and ST_n+1 may receive a gate high voltage VGH, a first gate low voltage VGL1, a second gate low voltage VGL2, a first clock signal CLK1, and a second clock signal CLK2. To this end, each of the stages ST_n−1, ST_n, and ST_n+1 may be connected to a gate high voltage line GHL, a first gate low voltage line GLL1, a second gate low voltage line GLL2, a first clock line CL1, and a second clock line CL2.

The gate high voltage line GHL may provide the gate high voltage VGH. The first gate low voltage line GLL1 may provide the first gate low voltage VGL1. The second gate low voltage line GLL2 may provide the second gate low voltage VGL2. The first clock line CL1 may provide the first clock signal CLK1. The second clock line CL2 may provide the second clock signal CLK2. The gate high voltage VGH may be greater than the first gate low voltage VGL1 and the second gate low voltage VGL2. The second gate low voltage VGL2 may be lower than the first gate low voltage VGL1. The first clock signal CLK1 and the second clock signal CLK2 may have different phases. In this case, the first gate high voltage VGH, the high voltage of the first clock signal CLK1, and the high voltage of the second clock signal CLK2 may be greater than the threshold voltage of each transistor in the stages ST_n−1, ST_n, and ST_n+1. In addition, the first gate low voltage VGL1, the second gate low voltage VGL2, the low voltage of the first clock signal CLK1, and the low voltage of the second clock signal CLK2 may be lower than the threshold voltage of each transistor in the stages ST_n−1, ST_n, and ST_n+1.

Each of the stages ST_n−1, ST_n, and ST_n+1 may output a first gate signal and a carry signal. For example, the n^{th} stage ST_n may output an n^{th} first gate signal GW_n and an n^{th} carry signal CR_n. The n^{th} first gate signal GW_n from the n^{th} stage ST_n may be applied to an n^{th} first gate line. The n^{th} carry signal CR_n from the n^{th} stage ST_n may be applied to at least one of a previous stage ST_n−1 or a subsequent stage ST_n+1.

Each of the stages ST_n−1, ST_n, and ST_n+1 may be connected to at least one of a previous stage or a subsequent stage. For example, an n^{th} gate output terminal of the n^{th} stage ST_n may be connected to an (n−2)^{th} stage and the (n+1)^{th} stage ST_n+1.

Each of the stages ST_n−1, ST_n, and ST_n+1 may be set by a carry signal from a previous stage and reset by a carry signal from a subsequent stage. For example, the n^{th} stage ST_n may be set by an (n−1)^{th} carry signal CR_n−1 from the (n−1)^{th} stage ST_n−1 and may be reset by an (n+2)^{th} carry signal from an (n+2)^{th} stage. When set, the stage ST_n asserts or activates its first gate signal GW_n. When reset, the stage ST_n deactivates its first gate signal GW_n.

During one frame period, a first stage, which outputs a first gate signal first among the stages, may be set by a frame line mark signal instead of a carry signal. Further, during one frame period, a first stage, which outputs or asserts a first gate signal last among the stages, may be reset by a carry signal from a separate dummy stage. The dummy stage may not output a first gate signal.

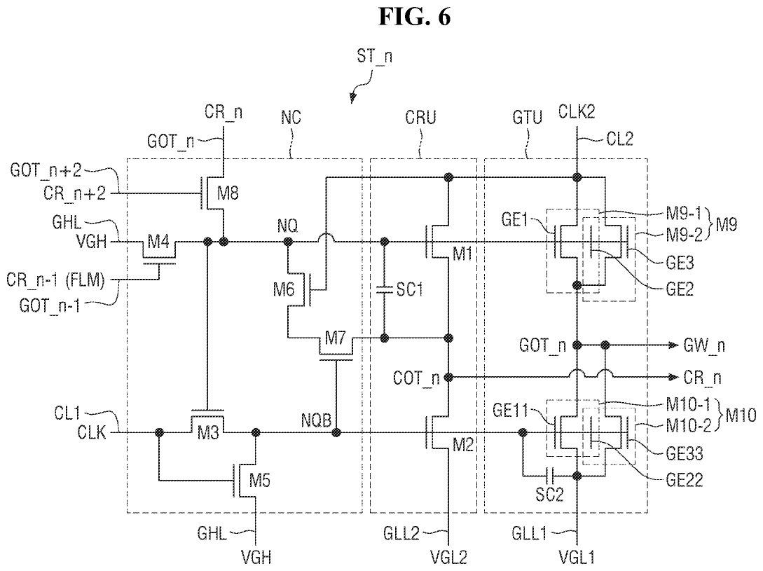

FIG. 6 is a circuit diagram of the n^{th} stage ST_n of FIG. 5.

As shown in FIG. 6, the n^{th} stage ST_n may include a node control unit NC, a carry output unit CRU, and a gate output unit GTU.

The n^{th} stage ST_n may include first to tenth transistors M1 to M10, a first capacitor SC1, and a second capacitor SC2. For example, the node control unit NC may include the third to eighth transistors M3 to M8. The carry output unit CRU may include the first transistor M1 and the second transistor M2. The gate output unit GTU may include the ninth transistor M9 and the tenth transistor M10. In this case, the ninth transistor M9 and the tenth transistor M10 may be output transistors that output the n^{th} first gate signal GW_n. For example, the ninth transistor M9 may be a pull-up transistor and the tenth transistor M10 may be a pull-down transistor.

A gate electrode of the first transistor M1 may be connected to a set node NQ, a drain electrode of the first transistor M1 may be connected to the second clock line CL2, and a source node of the first transistor M1 may be connected to a carry output terminal COT_n.

A gate electrode of the second transistor M2 may be connected to a reset node NQB, a drain electrode of the second transistor M2 may be connected to the carry output terminal COT_n, and a source electrode of the second transistor M2 may be connected to the second gate low voltage line GLL2.

A gate electrode of the third transistor M3 may be connected to the set node NQ, a drain electrode of the third transistor M3 may be connected to the first clock line CL1, and a source electrode of the third transistor M3 may be connected to the reset node NQB.

A gate electrode of the fourth transistor M4 may be connected to a start signal line or a carry output terminal COT_n−1 of the (n−1) stage ST_n−1, a drain electrode of the fourth transistor M4 may be connected to the gate high voltage line GHL, and a source electrode of the fourth transistor M4 may be connected to the set node NQ. In this case, the frame line mark signal described above may be applied to the start signal line, for example.

A gate electrode of the fifth transistor M5 may be connected to the first clock line CL1, a drain electrode of the fifth transistor M5 may be connected to the gate high voltage line GHL, and a source electrode of the fifth transistor M5 may be connected to the reset node NQB.

A gate electrode of the sixth transistor M6 may be connected to the second clock line CL2, a drain electrode of the sixth transistor M6 may be connected to the set node NQ, and a source electrode of the sixth transistor M6 may be connected to a source electrode of the seventh transistor M7.

A gate electrode of the seventh transistor M7 may be connected to the reset node NQB, a drain electrode of the seventh transistor M7 may be connected to the carry output terminal COT_n, and the source electrode of the seventh transistor M7 may be connected to the source electrode of the sixth transistor M6.

A gate electrode of the eighth transistor M8 may be connected to a carry output terminal COT_n+2 of the (n+2)^{th} stage, a drain electrode of the eighth transistor M8 may be connected to the set node NQ, and a source electrode of the eighth transistor M8 may be connected to the carry output terminal COT_n.

A gate electrode of the ninth transistor M9 may be connected to the set node NQ, a drain electrode of the ninth transistor M9 may be connected to the second clock line CL2, and a source electrode of the ninth transistor M9 may be connected to a gate output terminal GOT_n. Meanwhile, a gate electrode of the ninth transistor M9 may include a first gate electrode GE1 thereinafter referred to as a first lower gate electrode GE1), a second gate electrode GE2 (hereinafter referred to as a first common gate electrode GE2) and a third gate electrode GE3 (hereinafter referred to as a first upper gate electrode GE3). Here, the first lower gate electrode GE1, the first common gate electrode GE2, and the first upper gate electrode GE3 of the ninth transistor M9 may be connected to each other. The ninth transistor M9 may include, for example, a ninth-first sub-transistor M9-1 and a ninth-second sub-transistor M9-2. The ninth-first sub-transistor M9-1 may include the first lower gate electrode GE1, the first common gate electrode GE2, a first drain electrode DE1 and a first source electrode SEL. The first lower gate electrode GE1 and the first common gate electrode GE2 of the ninth-first sub-transistor M9-1 may be connected to the set node NQ, the first drain electrode DE1 of ninth-first sub-transistor M9-1 may be connected to the second clock line CL2, and the first source electrode SE1 of the ninth-first sub-transistor M9-1 may be connected to the gate output terminal GOT_n. The ninth-second sub-transistor M9-2 may include the first upper gate electrode GE3, the first common gate electrode GE2, a second drain electrode DE2 and a second source electrode SE2. The first upper gate electrode GE3 and the first common gate electrode GE2 of the ninth-second sub-transistor M9-2 may be connected to the set node NQ, the second drain electrode DE2 of ninth-second sub-transistor M9-2 may be connected to the second clock line CL2, and the second source electrode SE2 of the ninth-second sub-transistor M9-2 may be connected to the gate output terminal GOT_n.

A gate electrode of the tenth transistor M10 may be connected to the reset node NQB, a drain electrode of the tenth transistor M10 may be connected to the gate output terminal GOT_n, and a source electrode of the tenth transistor M10 may be connected to the first gate low voltage line GLL1. Meanwhile, the gate electrode of the tenth transistor M10 may include a first gate electrode GE11 (hereinafter referred to as a second lower gate electrode GE11), a second gate electrode GE22 (hereinafter referred to as a second common gate electrode GE22), and a third gate electrode GE33 (hereinafter referred to as a second upper gate electrode GE33). Here, the second lower gate electrode GE11, the second common gate electrode GE22 and the second upper gate electrode GE33 of the tenth transistor M10 may be connected to each other. The tenth transistor M10 may include, for example, a tenth-first sub-transistor M10-1 and a tenth-second sub-transistor M10-2. The tenth-first sub-transistor M10-1 may include the second lower gate electrode GE11, the second common gate electrode GE22, a third drain electrode, and a third source electrode. The second lower gate electrode GE11 and the second common gate electrode GE22 of the tenth-first sub-transistor M10-1 may be connected to the reset node NQB, the third drain electrode of the tenth-first sub-transistor M10-1 may be connected to the gate output terminal GOT_n, and the third source electrode of the tenth-first sub-transistor M10-1 may be connected to the first gate low voltage line GLL1. The tenth-second sub-transistor M10-2 may include the second upper gate electrode GE33, the second common gate electrode GE22, a fourth drain electrode and a fourth source electrode. The second upper gate electrode GE33 and the second common gate electrode GE22 of the tenth-second sub-transistor M10-2 may be connected to the reset node NQB, the fourth drain electrode of tenth-second sub-transistor M10-2 may be connected to the gate output terminal GOT_n, and the fourth source electrode of the tenth-second sub-transistor M10-2 may be connected to the first gate low voltage line GLL1.

The first electrode of the first capacitor SC1 may be connected to the set node NQ, and the second electrode of the first capacitor SC1 may be connected to the carry output terminal COT_n.

The first electrode of the second capacitor SC2 may be connected to the reset node NQB, and the second electrode of the second capacitor SC2 may be connected to the first gate low voltage line GLL1.

According to the present disclosure, since the ninth transistor M9, which is a pull-up transistor, includes the plurality of sub-transistors M9-1 and M9-2 connected in parallel, current driving ability of the ninth transistor M9 may be improved. In addition, since the plurality of sub-transistors M9-1 and M9-2 share at least one gate electrode GE2, the size of the ninth transistor M9 may be reduced. In other words, the pull-up transistor may be reduced in size while improving its current driving ability.

According to the present disclosure, since the tenth transistor M10, which is a pull-down transistor, includes the plurality of sub-transistors M10-1 and M10-2 connected in parallel, current driving ability of tenth transistor M10 may be improved. In addition, since the plurality of sub-transistors M10-1 and M10-2 share at least one gate electrode GE22, the size of the tenth transistor M10 may be reduced. In other words, the pull-down transistor may be reduced in size while improving its current driving ability.

Also, according to the present disclosure, as the sizes of the ninth transistor M9 and the tenth transistor M10 are reduced, the size of the gate driving circuit 400 may be reduced. When the size of the gate driving circuit 400 is decreased, the area of the non-display area (e.g., a dead space) where the gate driving circuit 400 is disposed may be decreased.

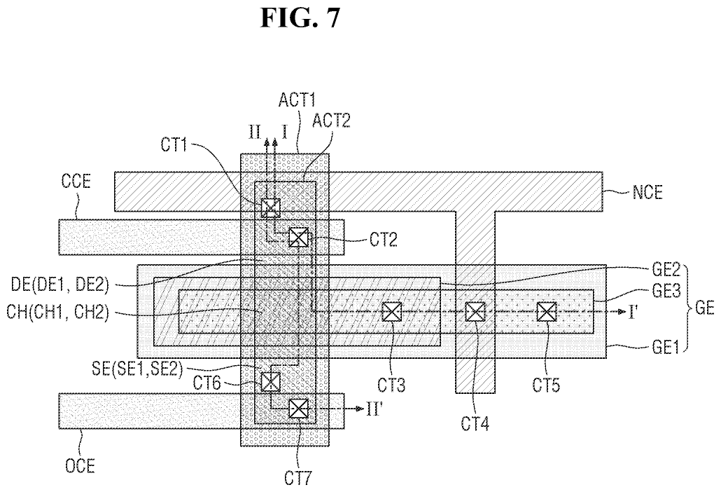

FIG. 7 is a plan view illustrating the layout of the ninth transistor M9 of FIG. 6.

The ninth transistor M9 may include a channel region CH, a gate electrode GE, a drain electrode DE, and a source electrode SE. For example, the ninth-first sub-transistor M9-1 of the ninth transistor M9 may include a first channel region CH1, a first lower gate electrode GE1, a first common gate electrode GE2, a first drain electrode DE1 and a first source electrode SE1, and the ninth-second sub-transistor M9-2 of the ninth transistor M9 may include a second channel region CH2, a first upper gate electrode GE3, the first common gate electrode GE2, a second drain electrode DE2 and a second source electrode SE2.

The first channel region CH1 of the ninth transistor M9 (or the ninth-first sub-transistor M9-1) may be disposed in an overlapping area between a first active layer ACT1 and at least one of the first lower gate electrode GE1 and the first common gate electrode GE2. For example, a region of the first active layer ACT1 overlapped by the first common gate electrode GE2 may be the first channel region CH1 described above. Further, regions of the first active layer ACT1 disposed on both sides of the first channel region CH1 may be the first drain electrode DE1 and the first source electrode SE1, respectively.

The second channel region CH2 of the ninth transistor M9 (or the ninth-second sub-transistor M9-2) may be disposed in an overlapping area between a second active layer ACT2 and at least one of the first upper gate electrode GE3 and the first common gate electrode GE2. For example, a region of the second active layer ACT2 overlapped by the first upper gate electrode GE3 may be the second channel region CH2 described above. Further, regions of the second active layer ACT2 disposed on both sides of the second channel region CH2 may be the second drain electrode DE2 and the second source electrode SE2, respectively.

The first lower gate electrode GE1 may overlap the first channel region CH1, the second channel region CH2, the first common gate electrode GE2, and the first upper gate electrode GE3. The first lower gate electrode GE1 may block light from being introduced into the first channel region CH1 of the first active layer ACT1 and the second channel region CH2 of the second active layer ACT2.

The first active layer ACT1 may be disposed on the first lower gate electrode GE1. The first active layer ACT1 may overlap the first lower gate electrode GE1. The first active layer ACT1 may include a first channel region CH1, a first drain electrode DE1, and a first source electrode SE1. The first channel region CH1 described above may be disposed in a portion of the first active layer ACT1 overlapping the first lower gate electrode GE1. The first active layer ACT1 may be an oxide semiconductor. For example, the first active layer ACT1 may include an oxide semiconductor including indium-gallium-zinc-oxide (IGZO) or an oxide semiconductor including indium-gallium-zinc-tin oxide (IGZTO).

The first common gate electrode GE2 may be disposed on the first active layer ACT1. The first common gate electrode GE2 may overlap the first active layer ACT1. The first channel region CH1 described above may be disposed in a portion of the first active layer ACT1 overlapping the first common gate electrode GE2.

The second active layer ACT2 may be disposed on the first common gate electrode GE2. The second active layer ACT2 may overlap the first common gate electrode GE2. The second active layer ACT2 may include a second channel region CH2, a second drain electrode DE2, and a second source electrode SE2. The second channel region CH2 described above may be disposed in a portion of the second active layer ACT2 overlapping the first common gate electrode GE2. The second active layer ACT2 may be connected to the first active layer ACT1 through a first contact hole CT1 and a sixth contact hole CT6 penetrating an insulating layer. For example, the second drain electrode DE2 of the second active layer ACT2 may be connected to the first drain electrode DE1 of the first active layer ACT1 through the first contact hole CT1, and the second source electrode SE2 of the second active layer ACT2 may be connected to the first source electrode SE1 of the first active layer ACT1 through the sixth contact hole CT6. The second active layer ACT2 may be an oxide semiconductor. For example, the second active layer ACT2 may include an oxide semiconductor including indium-gallium-zinc-oxide (IGZO) or an oxide semiconductor including indium-gallium-zinc-tin oxide (IGZTO). In this case, the second active layer ACT2 and the first active layer ACT1 may include the same semiconductor material (e.g., the same oxide semiconductor material). For example, each of the first active layer ACT1 and the second active layer ACT2 may be an oxide semiconductor including indium-gallium-zinc-oxide (IGZO). As another example, each of the first active layer ACT1 and the second active layer ACT2 may be an oxide semiconductor including indium-gallium-zinc-tin oxide (IGZTO).

The first upper gate electrode GE3 may be disposed on the second active layer ACT2. The first upper gate electrode GE3 may overlap the second active layer ACT2. The second channel region CH2 described above may be disposed in a portion of the second active layer ACT2 overlapping the first upper gate electrode GE3. The first upper gate electrode GE3 may be connected to the first common gate electrode GE2 through a third contact hole CT3 penetrating the insulating layer, and the first upper gate electrode GE3 may be connected to the first lower gate electrode GE1 through a fifth contact hole CT5 penetrating the insulating layer.

The first lower gate electrode GE1, the first active layer ACT1, the first common gate electrode GE2, the second active layer ACT2, and the first upper gate electrode GE3 described above may overlap each other. For example, the first lower gate electrode GE1, the first active layer ACT1, the first common gate electrode GE2, the second active layer ACT2, and the first upper gate electrode GE3 may overlap each other in the third direction DR3 perpendicular to the plan view of FIG. 7.

A node connection electrode NCE may be disposed on the first upper gate electrode GE3. The node connection electrode NCE may be connected to the first upper gate electrode GE3 through a fourth contact hole CT4 penetrating the insulating layer. Meanwhile, the node connection electrode NCE may be connected to the set node NQ shown in FIG. 6. Accordingly, the first lower gate electrode GE1, first common gate electrode GE2, and first upper gate electrode GE3 described above may be connected to the set node NQ through the node connection electrode NCE.

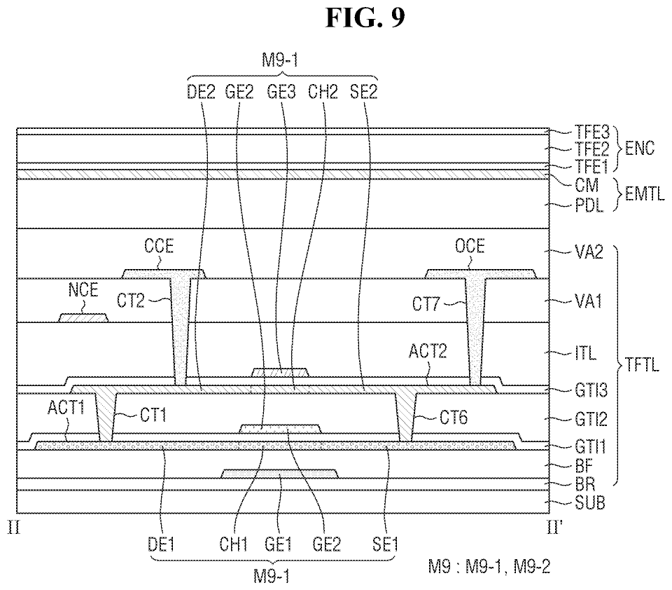

A clock connection electrode CCE and an output connection electrode OCE may be disposed on the node connection electrode NCE or in a conductive layer above the layer in which the node connection layer NCE is formed. The clock connection electrode CCE may be connected to the second drain electrode DE2 through a second contact hole CT2 penetrating the insulating layer. Meanwhile, the clock connection electrode CCE may be connected to the second clock line CL2 shown in FIG. 6. Accordingly, the first drain electrode DE1 and second drain electrode DE2 described above may be connected to the second clock line CL2 through the clock connection electrode CCE. The output connection electrode OCE may be connected to the second source electrode SE2 through a seventh contact hole CT7 penetrating the insulating layer. Meanwhile, the output connection electrode OCE may be connected to the gate output terminal GOT_n shown in FIG. 9. Accordingly, the first source electrode SE1 and second source electrode SE2 described above may be connected to the gate output terminal GOT_n through the output connection electrode OCE.

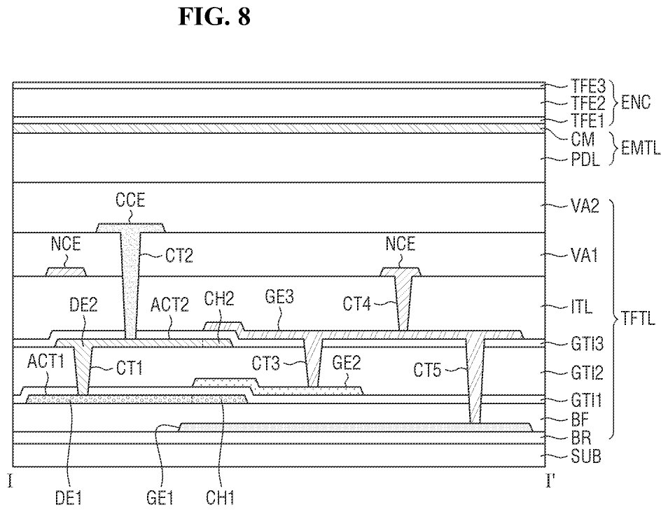

FIG. 8 is a cross-sectional view taken along line I-I′ of FIG. 7, and FIG. 9 is a cross-sectional view taken along line II-II′ of FIG. 7.

As shown in FIGS. 8 and 9, the display device 10 may include a substrate SUB, a barrier layer BR, a buffer layer BF, a thin film transistor layer TFTL, a light-emitting element layer EMTL, and an encapsulation layer ENC. The barrier layer BR, the buffer layer BF, the thin film transistor layer TFTL, the light-emitting element layer EMTL, and the encapsulation layer ENC may be sequentially disposed on the substrate SUB along the third direction DR3.

The substrate SUB may be a rigid substrate or a flexible substrate that can be bent, folded, or rolled. The substrate SUB may be formed of an insulating material such as glass, quartz, or a polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate CTA, cellulose acetate propionate (CAP), or a combination thereof. Alternatively, the substrate SUB may include a metal material.

The barrier layer BR may be disposed on the substrate SUB. The barrier layer BR may be a layer for protecting transistors of the thin film transistor layer TFTL and a light-emitting layer EL of the light-emitting element layer EMTL from moisture permeating through the substrate SUB, which may be susceptible to moisture permeation. The barrier layer BR may be formed as a plurality of inorganic layers that are alternately stacked. For example, the barrier layer BR may be formed of multiple layers in which one or more inorganic layers of a silicon nitride layer, a silicon oxynitride layer, a silicon oxide layer, a titanium oxide layer and an aluminum oxide layer are alternately stacked.

The first lower gate electrode GE1 may be disposed on the barrier layer BR.

The buffer layer BF may be disposed on the first lower gate electrode GE1. The buffer layer BF may be disposed on the entire surface of the substrate SUB including the first lower gate electrode GE1. The buffer layer BF may be a layer for protecting transistors of the thin film transistor layer TFTL and a light-emitting layer EL of the light-emitting element layer EMTL from moisture permeating through the substrate SUB, which may be susceptible to moisture permeation. The buffer layer BF may be formed as a plurality of inorganic layers that are alternately stacked. For example, the buffer layer BF may be formed of multiple layers in which one or more inorganic layers of a silicon nitride layer, a silicon oxynitride layer, a silicon oxide layer, a titanium oxide layer and an aluminum oxide layer are alternately stacked.

The first active layer ACT1 may be disposed on the buffer layer BF. For example, the first active layer ACT1 may be placed on the buffer layer BF such that the first channel region CH1 of the first active layer ACT1 overlaps the first lower gate electrode GE1 in the third direction DR3. For example, the first active layer ACT1 may be an oxide semiconductor. For example, the first active layer ACT1 may include an oxide semiconductor including indium-gallium-zinc-oxide (IGZO) or an oxide semiconductor including indium-gallium-zinc-tin oxide (IGZTO).

A first gate insulating layer GTI1 may be disposed on the first active layer ACT1. For example, the first gate insulating layer GTI1 may be disposed on the entire surface of the substrate including the first active layer ACT1. The first gate insulating layer GTI1 may include at least one of tetraethoxysilane (TEOS), silicon nitride (SiNx), and silicon oxide (SiO₂). For example, the first gate insulating layer GTI1 may have a double layer structure in which a silicon nitride layer having a thickness of 40 nm and a tetraethoxysilane layer having a thickness of 80 nm are sequentially stacked.

The first common gate electrode GE2 may be disposed on the first gate insulating layer GTI1. The first common gate electrode GE2 may be disposed on the first gate insulating layer GTI1 to overlap the first channel region CH1 of the first active layer ACT1.

A second gate insulating layer GTI2 may be disposed on the first common gate electrode GE2. The second gate insulating layer GTI2 may be disposed on the entire surface of the substrate SUB including the first common gate electrode GE2. The second gate insulating layer GTI2 may include the same material and structure as the first gate insulating layer GTI1 described above.

The second active layer ACT2 may be disposed on the second gate insulating layer GTI2. For example, the second active layer ACT2 may be disposed on the second gate insulating layer GTI2 such that the second channel region CH2 of the second active layer ACT2 overlaps the first common gate electrode GE2 in the third direction DR3. Also, the second active layer ACT2 may overlap the first active layer ACT1 in the third direction DR3. The second drain electrode DE2 of the second active layer ACT2 may be connected to the first drain electrode DE1 of the first active layer ACT1 through a first contact hole CT1 penetrating the second gate insulating layer GTI2 and the first gate insulating layer GTI1, and the second source electrode SE2 of the second active layer ACT2 may be connected to the first source electrode SE1 of the first active layer ACT1 through a sixth contact hole CT6 penetrating the second gate insulating layer GTI2 and the first gate insulating layer GTI1.

The second active layer ACT2 may be a semiconductor such as an oxide semiconductor. For example, the second active layer ACT2 may include an oxide semiconductor including indium-gallium-zinc-oxide (IGZO) or an oxide semiconductor including indium-gallium-zinc-tin oxide (IGZTO).

The third gate insulating layer GTI3 may be disposed on the second active layer ACT2. The third gate insulating layer GTI3 may be disposed on the entire surface of the substrate SUB including the second active layer ACT2. The third gate insulating layer GTI3 may include the same material and structure as the first gate insulating layer GTI1 described above.

A first upper gate electrode GE3 may be disposed on the third gate insulating layer GTI3. The first upper gate electrode GE3 may be disposed on the third gate insulating layer GTI3 to overlap the second channel region CH2 of the second active layer ACT2. The first upper gate electrode GE3 may be connected to the first common gate electrode GE2 through a third contact hole CT3 penetrating the third gate insulating layer GTI3 and the second gate insulating layer GTI2. In addition, the first upper gate electrode GE3 may be connected to the first lower gate electrode GE1 through a fifth contact hole CT5 penetrating the third gate insulating layer GTI3, the second gate insulating layer GTI2, the first gate insulating layer GTI1 and the buffer layer BF.

An interlayer insulating layer ITL may be disposed on the first upper gate electrode GE3. The interlayer insulating layer ITL may be disposed on the entire surface of the substrate SUB including the first upper gate electrode GE3. The interlayer insulating layer ITL may include an inorganic layer, for example, a silicon nitride layer, a silicon oxynitride layer, a silicon oxide layer, a titanium oxide layer, or an aluminum oxide layer. Meanwhile, the interlayer insulating layer ITL may include a plurality of inorganic layers.

The node connection electrode NCE may be disposed on the interlayer insulating layer ITL. The node connection electrode NCE may be connected to the first upper gate electrode GE3 through a fourth contact hole CT4 penetrating the interlayer insulating layer ITL.

A first planarization layer VA1 may be disposed on the node connection electrode NCE. The first planarization layer VA1 may be disposed on the entire surface of the substrate SUB including the node connection electrode NCE. The first planarization layer VA1 may be formed as an organic layer such as a layer of an acryl resin, an epoxy resin, a phenolic resin, a polyamide resin, and a polyimide resin.

The clock connection electrode CCE and an output connection electrode OCE may be disposed on the first planarization layer VAL. The clock connection electrode CCE may be connected to the second drain electrode DE2 of the second active layer ACT2 through a second contact hole CT2 penetrating the first planarization layer VA1, the interlayer insulating layer ITL and the third gate insulating layer GTI3, and the output connection electrode OCE may be connected to the second source electrode SE2 of the second active layer ACT2 through a seventh contact hole CT7 penetrating the first planarization layer VA1, the interlayer insulating layer ITL and the third gate insulating layer GTI3.

A second planarization layer VA2 may be disposed on the clock connection electrode CCE and the output connection electrode OCE. The second planarization layer VA2 may be disposed on the entire surface of the substrate SUB including the clock connection electrode CCE and the output connection electrode OCE. The second planarization layer VA2 may include the same material and structure as the first planarization layer VA1 described above.

A bank PDL (or pixel definition layer) may be disposed on the second planarization layer VA2. The bank PDL serves to define the emission areas of the pixels. To this end, the bank PDL may be disposed to expose a partial region of the pixel electrode (e.g., anode electrode) on the second planarization layer VA2. The bank PDL may cover the edge of the pixel electrode. The bank PDL may be formed of an organic layer such as a layer of acryl resin, epoxy resin, phenolic resin, polyamide resin, polyimide resin and the like.

A common electrode CM may be disposed on the bank PDL. Meanwhile, the light-emitting element LEL may include the pixel electrode, a light-emitting layer on the pixel electrode, and the common electrode CM contacting the light-emitting layer. The emission area represents an area in which the pixel electrode, the light-emitting layer, and the common electrode CM are sequentially stacked and holes from the pixel electrode and electrons from the common electrode CM are combined with each other in the light-emitting layer to emit light. In this case, the pixel electrode may be the anode electrode of the light-emitting element, and the common electrode CM may be the cathode electrode of the light-emitting element LEL.

The light-emitting layer may include an organic material to emit a predetermined color. For example, the light-emitting layer may include a hole transporting layer, an organic material layer, and an electron transporting layer. The organic material layer may include a host and a dopant. The organic material layer may include a material that emits light of a predetermined wavelength and may be formed using a phosphorescent material or a fluorescent material.

The organic material layer may include different areas containing different types of organic materials or layers to emit different colors of light. For example, the organic material layer may include a first light-emitting layer in a first emission area emitting light of a first color. The organic material layer may include a phosphorescent material including a host material including carbazole biphenyl (CBP) or mCP (1,3-bis(carbazol-9-yl), and a dopant including at least one selected from the group consisting of
PIQIr(acac)(bis(1-phenylisoquinoline)acetylacetonate iridium),
PQIr(acac)(bis(1-phenylquinoline)acetylacetonate iridium),
PQIr(tris(1-phenylquinoline)iridium)) and PtOEP (octaethylporphyrin platinum).
   Alternatively, the organic material layer of the first light-emitting layer of the first emission area may be a fluorescent material including PBD:Eu(DBM)3(Phen) or Perylene, but the present disclosure is not limited thereto.

The organic material layer of a second light-emitting layer in a second emission area emitting light of a second color may be a phosphorescent material including a host material including CBP or mCP, and a dopant material including Ir(ppy)3(fac tris(2-phenylpyridine)iridium. Alternatively, the organic material layer of the second light-emitting layer of the second emission area emitting the light of the second color may be a fluorescent material including tris(8-hydroxyquinolino)aluminum (Alq3), but the present disclosure is not limited thereto.

The organic material layer of a third light-emitting layer in a third emission area emitting light of a third color may be a phosphorescent material including a host material including CBP or mCP, and a dopant material including (4,6-F2ppy)2Irpic or L2BD111, but the present disclosure is not limited thereto.

The aforementioned common electrode CM may be disposed on the first, second, and third light-emitting layers. The common electrode CM may be disposed to cover the first, second, and third light-emitting layers. The common electrode CM may be a common layer commonly disposed in the first to third light-emitting layers. A capping layer may be formed on the common electrode CM.

In the top emission structure, the common electrode CM may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CM is formed of a semi-transmissive conductive material, the light emission efficiency can be increased due to a micro-cavity effect.

In a top emission structure that emits light toward the common electrode CM with respect to the light-emitting layer, the pixel electrode may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

A spacer may be disposed on the bank PDL. The spacer may serve to support a mask during a process of manufacturing the light-emitting layer EL. The spacer may be formed of an organic layer such as a layer of acryl resin, epoxy resin, phenolic resin, polyamide resin, polyimide resin and the like.

The encapsulation layer ENC may be formed on the light-emitting element layer EMTL. The encapsulation layer ENC may include at least one inorganic layer TFE1 and TFE3 to prevent oxygen or moisture from permeating into the light-emitting element layer EMTL. In addition, the encapsulation layer ENC may include at least one organic layer to protect the light-emitting element layer EMTL from foreign substances such as dust. For example, the encapsulation layer ENC may include a first inorganic encapsulation layer TFE1, an organic encapsulation layer TFE2, and a second inorganic encapsulation layer TFE3.

The first inorganic encapsulation layer TFE1 may be disposed on the common electrode CM, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed of a multilayer in which one or more inorganic layers of a silicon nitride layer, a silicon oxynitride layer, a silicon oxide layer, a titanium oxide layer, and an aluminum oxide layer are alternately stacked. The organic encapsulation layer TFE2 may be an organic layer such as a layer of acryl resin, epoxy resin, phenolic resin, polyamide resin, polyimide resin or the like.

Meanwhile, although not shown, the tenth transistor M10 of FIG. 6 may have the same configuration as the ninth transistor M9 of FIGS. 7, 8, and 9 described above.

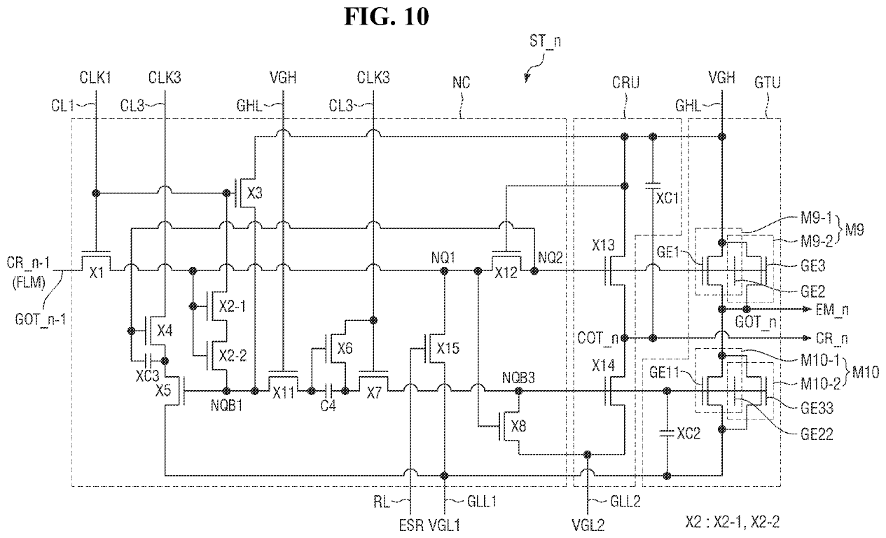

FIG. 10 is a circuit diagram of an embodiment of one stage (e.g., n^{th} stage EST_n) included in the emission control driver 450 of FIG. 3. Control driver 450 as described above applies the emission control signal to the emission signal EML to the emission lines EML. The emission lines EML include a plurality of emission lines, and for any integer n less than or equal to the number of the emission lines EML, the n^{th} stage applies an emission signal EM_n to the n^{th} emission line.

As shown in FIG. 10, the n^{th} stage EST_n may include a node control unit NC, a carry output unit CRU, and a gate output unit GTU.

The n^{th} stage EST_n may include first to eighth transistors X1 to X8, the transistors M9 and M10, and eleventh to fifteenth transistors X11 to X15, a first capacitor XC1, a second capacitor XC2, and a third capacitor XC3. For example, the node control unit NC may include the first to eighth transistors X1 to X8, the eleventh transistor X11, a twelfth transistor X12, and the fifteenth transistor X15. The carry output unit CRU may include a thirteenth transistor X13 and a fourteenth transistor X14. The gate output unit GTU may include the ninth transistor M9 and the tenth transistor M10. In this case, the ninth transistor M9 and the tenth transistor M10 may be output transistors that output the n^{th} emission signal EM_n. For example, the ninth transistor M9 may be a pull-up transistor and the tenth transistor M10 may be a pull-down transistor.

A gate electrode of the first transistor X1 may be connected to the first clock line CL1, a drain electrode of the first transistor X1 may be connected to the carry output terminal COT_n−1 of the (n−1) stage, and a source electrode of the first transistor X1 may be connected to a first set node NQ1.

A gate electrode of the second transistor X2 may be connected to the first set node NQ1, a drain electrode of the second transistor X2 may be connected to the first clock line CL1, and a source electrode of the second transistor X2 may be connected to a first reset node NQB1. Meanwhile, the second transistor X2 may include a second-first sub-transistor X2-1 and a second-second sub-transistor X2-2 connected in series between the first clock line CL1 and the first reset node NQB1.

The gate electrode of the third transistor X3 may be connected to the first clock line CL1, the drain electrode of the third transistor X3 may be connected to the gate high voltage line GHL, and the source electrode of the third transistor X3 may be connected to the first reset node NQB1.

The gate electrode of the fourth transistor X4 may be connected to a second set node NQ2, the drain electrode of the fourth transistor X4 may be connected to a third clock line CL3, and the source electrode of the fourth transistor X4 may be connected to the drain electrode of the fifth transistor X5.

The gate electrode of the fifth transistor X5 may be connected to the first reset node NQB1, the drain electrode of the fifth transistor X5 may be connected to the source electrode of the fourth transistor X4, and the source electrode of the fifth transistor X5 may be connected to the first gate low voltage line GLL1.

The gate electrode of the sixth transistor X6 may be connected to a second reset node NQB2, the drain electrode of the sixth transistor X6 may be connected to the third clock line CL3, and the source electrode of the sixth transistor S6 may be connected to the drain electrode of the seventh transistor X7.

The gate electrode of the seventh transistor X7 may be connected to the third clock line CL3, the drain electrode of the seventh transistor X7 may be connected to the source electrode of the sixth transistor X6, and the source electrode of the seventh transistor X7 may be connected to a third reset node NQB3.

The gate electrode of the eighth transistor X8 may be connected to the first set node NQ1, the drain electrode of the eighth transistor X8 may be connected to the third reset node NQB3, and the source electrode of the eighth transistor X8 may be connected to the second gate low voltage line GLL2.

The gate electrode of the ninth transistor M9 may be connected to the second set node NQ2, the drain electrode of the ninth transistor M9 may be connected to the gate high voltage line GHL, and the source electrode of the ninth transistor M9 may be connected to the gate output terminal GOT_n. Meanwhile, the gate electrode of the ninth transistor M9 may include a first gate electrode GE1 (hereinafter referred to as a first lower gate electrode GE1), a second gate electrode GE2 (hereinafter referred to as a first common gate electrode GE2), and a third gate electrode GE3 (hereinafter referred to as a first upper gate electrode GE3). Here, the first lower gate electrode GE1, the first common gate electrode GE2 and the first upper gate electrode GE3 of the ninth transistor M9 may be connected to each other. The ninth transistor M9 may include, for example, a ninth-first sub-transistor M9-1 and a ninth-second sub-transistor M9-2. The ninth-first sub-transistor M9-1 may include a first lower gate electrode GE1, a first common gate electrode GE2, a first drain electrode DE1, and a first source electrode SEL. The first lower gate electrode GE1 and the first common gate electrode GE2 of the ninth-first sub-transistor M9-1 may be connected to the set node NQ, the first drain electrode DE1 of ninth-first sub-transistor M9-1 may be connected to the second clock line CL2, and the first source electrode SE1 of the ninth-first sub-transistor M9-1 may be connected to the gate output terminal GOT_n. The ninth-second sub-transistor M9-2 may include a first upper gate electrode GE3, a first common gate electrode GE2, a second drain electrode DE2 and a second source electrode SE2. The first upper gate electrode GE3 and the first common gate electrode GE2 of the ninth-second sub-transistor M9-2 may be connected to the second set node NQ2, the second drain electrode DE2 of ninth-second sub-transistor M9-2 may be connected to the gate high voltage line GHL, and the second source electrode SE2 of the ninth-second sub-transistor M9-2 may be connected to the gate output terminal GOT_n.

The gate electrode of the tenth transistor M10 may be connected to the third reset node NQB3, the drain electrode of the tenth transistor M10 may be connected to the gate output terminal GOT_n, and the source electrode of the tenth transistor M10 may be connected to the first gate low voltage line GLL1. Meanwhile, the gate electrode of the tenth transistor M10 may include a first gate electrode GE11 (hereinafter referred to as a second lower gate electrode GE11), a second gate electrode GE22 (hereinafter referred to as a second common gate electrode GE22), and a third gate electrode GE33 (hereinafter referred to as a second upper gate electrode GE33). Here, the second lower gate electrode GE11, the second common gate electrode GE22, and the second upper gate electrode GE33 of the tenth transistor M10 may be connected to each other. The tenth transistor M10 may include, for example, a tenth-first sub-transistor M10-1 and a tenth-second sub-transistor M10-2. The tenth-first sub-transistor M10-1 may include the second lower gate electrode GE11, the second common gate electrode GE22, a third drain electrode and a third source electrode. The second lower gate electrode GE11 and the second common gate electrode GE22 of tenth-first sub-transistor M10-1 may be connected to the third reset node NQB3, the third drain electrode of the tenth-first sub-transistor M10-1 may be connected to the gate output terminal GOT_n, and the third source electrode of the tenth-first sub-transistor M10-1 may be connected to the first gate low voltage line GLL1. The tenth-second sub-transistor M10-2 may include a second upper gate electrode GE33, a second common gate electrode GE22, a fourth drain electrode and a fourth source electrode. The second upper gate electrode GE33 and the second common gate electrode GE22 of the tenth-second sub-transistor M10-2 may be connected to the third reset node NQB3, the fourth drain electrode of the tenth-second sub-transistor M10-2 may be connected to the gate output terminal GOT_n, and the fourth source electrode of the tenth-second sub-transistor M10-2 may be connected to the first gate low voltage line GLL1.

A gate electrode of the eleventh transistor X11 may be connected to the gate high voltage line GHL, a drain electrode of the eleventh transistor X11 may be connected to the first reset node NQB1, and a source electrode of the eleventh transistor X11 may be connected to the second reset node NQB2.

A gate electrode of the twelfth transistor X12 may be connected to the gate high voltage line GHL, a drain electrode of the twelfth transistor X12 may be connected to the first set node NQ1, and a source electrode of the twelfth transistor X12 may be connected to the second set node NQ2.

A gate electrode of the thirteenth transistor X13 may be connected to the second set node NQ2, a drain electrode of the thirteenth transistor X13 may be connected to the gate high voltage line GHL, and a source electrode of the thirteenth transistor X13 may be connected to the carry output terminal COT_n.

A gate electrode of the fourteenth transistor X14 may be connected to the third reset node NQB3, a drain electrode of the fourteenth transistor X14 may be connected to the carry output terminal COT_n, and a source electrode of the fourteenth transistor X14 may be connected to the second gate low voltage line GLL2.

A gate electrode of the fifteenth transistor X15 may be connected to a reset signal line RL, a drain electrode of the fifteenth transistor X15 may be connected to the first set node NQ1, and a source electrode of the fifteenth transistor X15 may be connected to the first gate low voltage line GLL1. Here, the reset signal line RL may transmit a reset signal ESR. The reset signal ESR may have, for example, the same level as the gate high voltage VGH. In another embodiment, the reset signal ESR may be the (n+2)^{th} carry signal from the subsequent stage (e.g., (n+2)^{th} stage) of the emission control driver. The reset signal ESR may be simultaneously applied to the gate electrodes of the fifteenth transistors X15 provided in all stages of the emission control driver 450, for example.

The first electrode of the first capacitor XC1 may be connected to the gate high voltage line GHL, and the second electrode of the first capacitor XC1 may be connected to the carry output terminal COT_n.

The first electrode of the second capacitor XC2 may be connected to the third reset node NQB3, and the second electrode of the second capacitor XC2 may be connected to the first gate low voltage line GLL1.

The first electrode of the third capacitor XC3 may be connected to the second set node NQ2, and the second electrode of the third capacitor XC3 may be connected to the source electrode of the fourth transistor X4.

The first electrode of the fourth capacitor XC4 may be connected to the second reset node NQB2, and the second electrode of the fourth capacitor XC4 may be connected to the source electrode of the sixth transistor X6.

Meanwhile, although not shown, at least one of the ninth transistor M9 and the tenth transistor M10 of FIG. 10 may have the same configuration as the ninth transistor M9 of FIGS. 7, 8, and 9 described above.

In concluding the detailed description, those skilled in the art will appreciate that many variations and modifications can be made to the described embodiments without substantially departing from the principles of the present disclosure. Therefore, the disclosed described embodiments of the invention are used in a generic and descriptive sense only and not for purposes of limitation.

What is claimed is:

1. A display device comprising:
a substrate having a display area and a non-display area;
pixels arranged in the display area of the substrate; and
a gate driving circuit disposed in the non-display area of the substrate and connected to a transistor of the pixel,
wherein the gate driving circuit includes a pull-up transistor and a pull-down transistor,
wherein at least one of the pull-up transistor and the pull-down transistor includes a plurality of sub-transistors including a plurality of gate electrodes, and
wherein the sub-transistors share at least one of the gate electrodes.

2. The display device of claim 1,
wherein the plurality of gate electrodes comprises:
a first gate electrode disposed on the substrate;
a second gate electrode disposed on the first gate electrode; and
a third gate electrode disposed on the second gate electrode.

3. The display device of claim 2,
wherein the plurality of sub-transistors shares the second gate electrode.

4. The display device of claim 3,
wherein the plurality of sub-transistors comprises a first sub-transistor and a second sub-transistor connected in parallel.

5. The display device of claim 4,
wherein the first sub-transistor comprises:
the first gate electrode;
the second gate electrode; and
a first active layer disposed between the first gate electrode and the second gate electrode.

6. The display device of claim 5,
wherein the second sub-transistor comprises:
the second gate electrode;
the third gate electrode; and
a second active layer disposed between the second gate electrode and the third gate electrode.

7. The display device of claim 6,
wherein a portion of the first active layer corresponding to a first drain electrode of the first sub-transistor and a portion of the second active layer corresponding to a second drain electrode of the second sub-transistor are connected to each other.

8. The display device of claim 7,
wherein the first drain electrode and the second drain electrode are connected to each other through a contact hole in an insulating layer.

9. The display device of claim 6,
wherein a portion of the first active layer corresponding to a first source electrode of the first sub-transistor and a portion of the second active layer corresponding to a second source electrode of the second sub-transistor are connected to each other.

10. The display device of claim 9,
wherein the first source electrode and the second source electrode are connected to each other through a contact hole in an insulating layer.

11. The display device of claim 6,
wherein the first active layer and the second active layer contain the same semiconductor material.

12. The display device of claim 11,
wherein the first active layer and the second active layer each contains oxide semiconductor material.

13. The display device of claim 12,
wherein the oxide semiconductor material includes an oxide semiconductor including indium-gallium-zinc-oxide (IGZO) or indium-gallium-zinc-tin oxide (IGZTO).

14. The display device of claim 6,
wherein the first active layer and the second active layer overlap each other.

15. The display device of claim 2,
wherein the first gate electrode, the second gate electrode, and the third gate electrode are connected to each other through a contact hole in an insulating layer.

16. The display device of claim 2,
wherein the first gate electrode, the second gate electrode, and the third gate electrode overlap each other.
